(19) United States
(12) Patent Application Publication
(10) Pub. No.: US 2017/0004801 A1
(43) Pub. Date: Jan. 5, 2017

(54) SHIFT REGISTER AND DRIVING METHOD THEREOF

(71) Applicants: Shanghai Tianma AM-OLED Co., Ltd., Shanghai (CN); Tianma Micro-Electronics Co., Ltd., Shenzhen (CN)

(72) Inventors: Yuan Li, Xiamen (CN); Dong Qian, Shanghai (CN)

(21) Appl. No.: 15/159,820

(22) Filed: May 20, 2016

(30) Foreign Application Priority Data
Jun. 30, 2015 (CN) 201510374045.X

(51) Int. Cl. G09G 5/00; G11C 19/28

(52) U.S. Cl. CPC G09G 5/003; G11C 19/28; G09G 2300/0426; G09G 2310/0286; G09G 2310/08; G09G 2330/021

(57) ABSTRACT

The present disclosure provides a shift register and a driving method thereof The shift register includes an input control module, a first output module, a second output module, a stabilizing module. The input control module and the stabilizing module control activation of the first output module, for outputting a second level signal from the second level signal terminal to the signal output terminal, or control activation of the second output module, for outputting a second clock signal from the second clock terminal to the signal output terminal, so as to make a secondary shift register to be operated normally. The shift register in accordance with the present disclosure has an excellent stability, a better transmission and a good performance, thereby solving problems of poor stability and unstable operation of the shift registers in the prior art.

### CROSS-REFERENCES TO RELATED APPLICATIONS

This application claims priority to a Chinese patent application No. CN201510374045.X filed on Jun. 30, 2015 and entitled “Shift Register And Driving Method Thereof”, the disclosure of which is incorporated herein by reference in its entirety.

### TECHNICAL FIELD

The present application relates to the field of displaying technologies, in particular to a shift register and a driving method thereof.

### BACKGROUND

A shift register is usually configured to store data, and also configured to sequentially shift the data therein to the left or right under the action of clock signals.

FIG. 1 is a schematic view showing the structure of a shift register in the related art, and FIG. 2 is a timing diagram of a circuit of the shift register in FIG. 1. As shown in FIGS. 1 and 2, VGH represents a high level signal, VGL represents a low level signal, CK and CKB are clock signals having inverse phases to each other. In such a register, two cases would occur at an instant of a transition of the clock signal between a time period T1 and a time period T2: in the first case, the clock signal CK is changed to a low level, a node N1 still keeps, at the beginning of the jump, a same low level as in the preceding time, a fourth transistor M4 is turned on, and hence a signal output terminal OUT outputs a low level of the clock signal CKB; in the second case, the clock signal CK is changed to a low level, a first transistor M1 is turned off, a node N2 still keeps a same low level as in the preceding time, a third transistor M3 is turned on, and hence the signal output terminal OUT outputs a high level signal VGH. In other words, in the instant of the transition of the clock signal, there exists a competitive risk in the shift register in the related art, thereby affecting the stability of the circuit.

### SUMMARY

An embodiment of the present disclosure is to provide a shift register, where the shift register includes: an input control module, a first output module, a second output module, a stabilizing module, a signal input terminal, a signal output terminal, a first clock terminal, a second clock terminal, a first level signal terminal and a second level signal terminal. The signal input terminal is configured to receive a first pulse signal, the signal output terminal is configured to output a second pulse signal. The first clock terminal is configured to receive a first clock signal. The second clock terminal is configured to receive a second clock signal. The first level signal terminal is configured to receive a first level signal and the second level signal terminal is configured to receive a second level signal. The input control module, the stabilizing module and the second output module are electrically connected at a first node. The input control module and the first output module are electrically connected at a second node. The input control module comprises a first transistor, a second transistor and a first capacitor. A gate electrode of the first transistor is connected to the first clock terminal. A source electrode of the first transistor is connected to the first level signal terminal. A drain electrode of the first transistor is connected to the second node. A gate electrode of the second transistor is connected to the first node. A source electrode of the second transistor is connected to the signal input terminal. A drain electrode of the second transistor is connected to the second node. The first capacitor is connected between the second node and the second level signal terminal. The second output module is connected to the signal output terminal and the second clock terminal.

The first output module is connected to signal output terminal and the second level signal terminal. The stabilizing module is connected to the signal input terminal, the first clock terminal.

An embodiment of the present disclosure is to provide a driving method for the above shift register. Under the method, in a signal input phase, the following operations take place: the first transistor is turned on, so that a first level signal from the first level signal terminal is transmitted to the second node; the stabilizing module transmits a first pulse signal from the signal input terminal to the first node; the first output module outputs a second level signal from the second level signal terminal; the second output module outputs a second clock signal from the second clock terminal; the signal output terminal receives the second level signal and the second clock signal and outputs a second pulse signal;

Under the method, in a signal output phase, the following operations take place: the first transistor is turned off, the second transistor is turned on, so that the first pulse signal is transmitted to the second node; the second output module outputs the second clock signal from the second clock terminal; the signal output terminal receives the second clock signal and outputs the second pulse signal.

Under the method, in a signal reset phase, the following operations take place: the first transistor is turned on, so that the first level signal is transmitted from the first level signal terminal to the second node; the stabilizing module transmits the first pulse signal to the first node; the first output module outputs the second level signal from the second level signal terminal; the signal output terminal receives the second level signal and outputs the second pulse signal.

In the method, the first pulse signal is at a first level state in the signal input phase, and is at a second level state in the signal output phase and the signal reset phase; the second pulse signal is at a first level state in the signal output phase, and is at a second level state in the signal input phase and the signal reset phase.

According to the shift register and the driving method for the shift register provided by the present disclosure, the input control module and the stabilizing module are configured to control the activation of the first output module so as to transmit the second level signal from the second level signal terminal to the signal output terminal, or are configured to control the activation of the second output module so as to transmit the second clock signal from the second clock terminal to the signal output terminal, thereby making the secondary shift register to be in operation normally. The shift register provided by the present disclosure achieves a good stability, a better transmission and a good performance, thereby solving problems of poor stability and unstable operation of the shift registers in the prior art.

### DESCRIPTION OF DRAWINGS

FIG. 1 is a schematic view showing the structure of a shift register provided in the related art;

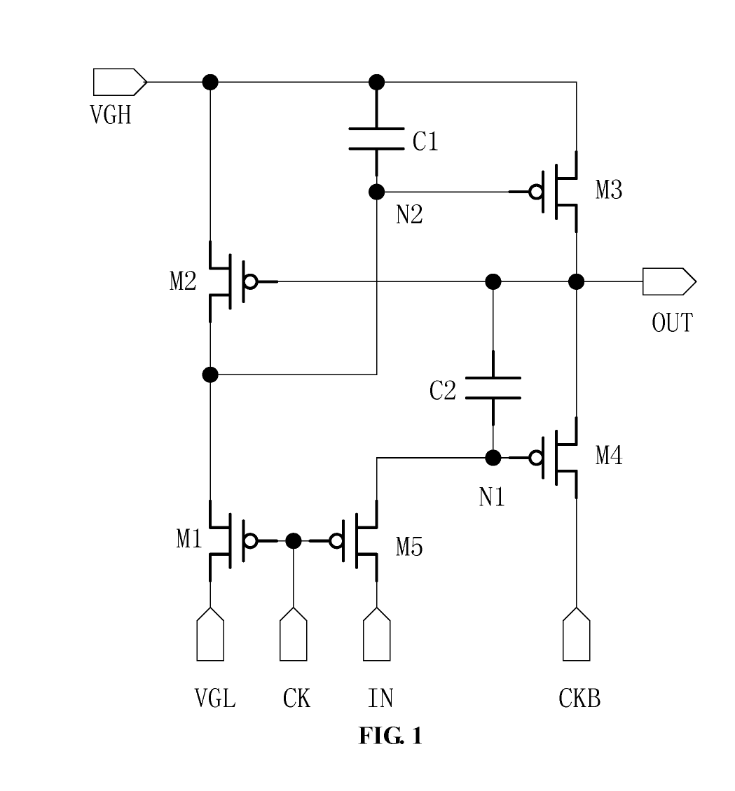

FIG. 2 is a schematic view showing the driving time sequence of the shift register in FIG. 1;

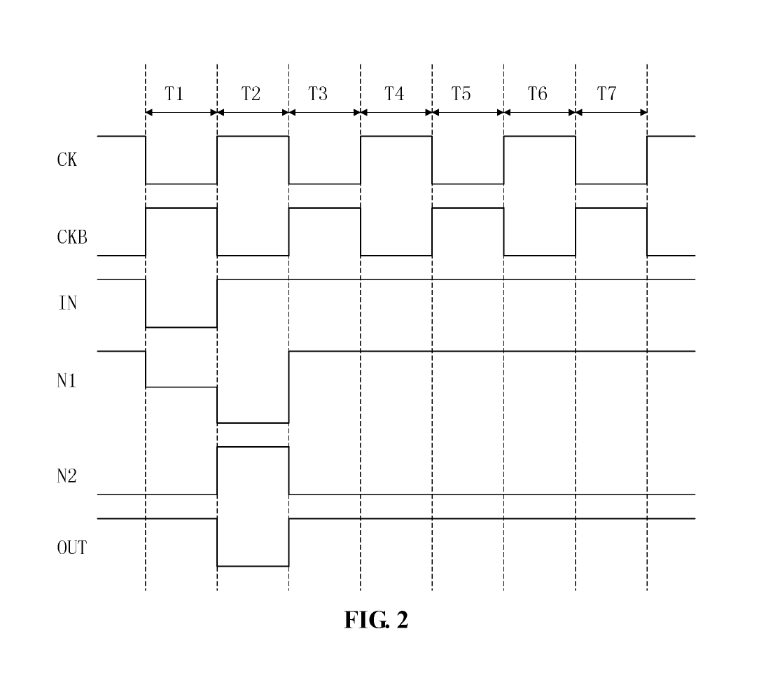

FIG. 3 is a schematic view showing the structure of a shift register in accordance with an embodiment of the present disclosure;

FIG. 4 is a schematic view showing the driving time sequence of the shift register in FIG. 3;

FIG. 5 is a schematic view showing another driving time sequence of the shift register in FIG. 3;

FIG. 6 is a schematic view showing the structure of another shift register provided in an embodiment of the present disclosure.

### DETAILED DESCRIPTION OF THE EMBODIMENTS

The embodiments of the present disclosure will be described below in detail with reference to the drawings, in order to make the objects, technical features and advantages of the present disclosure more clearly and readily understood.

It should be understood that the specific details of the present disclosure is described in the following for entirely understanding the present disclosure. The present disclosure can be achieved by other alternatives different from the present disclosure. Those skilled in the art can implement the embodiments of the present disclosure without departing from the spirit or the protection scope of the present disclosure. Therefore, the present disclosure is not limited by the embodiments shown herein.

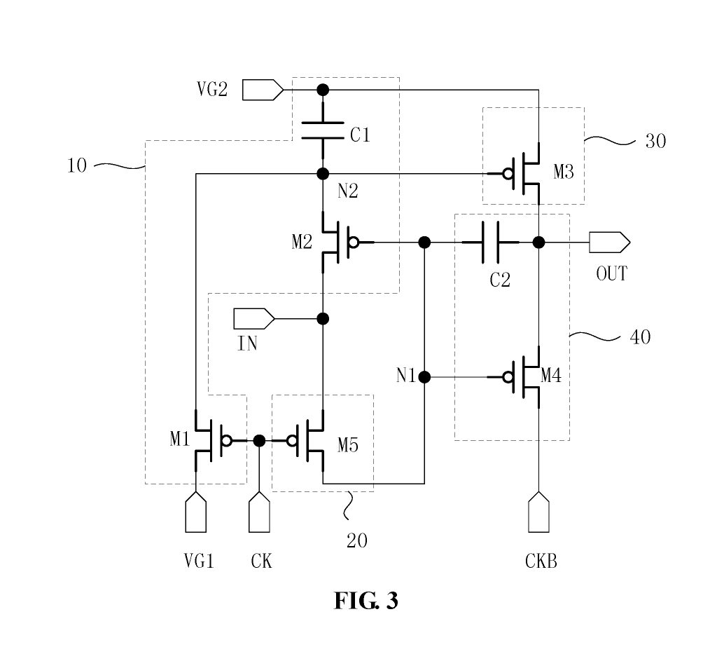

Referring to FIG. 3, FIG. 3 is a schematic view showing the structure of a shift register in accordance with an embodiment of the present disclosure. The shift register shown in FIG. 3 includes an input control module 10, a first output module 30, a second output module 40, a stabilizing module 20, a signal input terminal IN, a signal output terminal OUT, a first clock terminal CK, a second clock terminal CKB, a first level signal terminal VG1 and a second level signal terminal VG2. A signal input terminal IN of a stage of shift register is configured to receive a first pulse signal outputted by the preceding stage of shift register in order to enable the stage of shift register. A signal output terminal OUT of a stage of shift register is configured to output a second pulse signal for driving electronic elements connected to the stage of shift register and for enabling the next stage of shift register. The first clock terminal CK is configured to receive a first clock signal, the second clock terminal CKB is configured to receive a second clock signal, the first level signal terminal VG1 is configured to receive a first level signal and the second level signal terminal VG2 is configured to receive a second level signal.

As shown, the input control module 10, the stabilizing module 20 and the second output module 40 are electrically connected at a first node N1. As also shown, the input control module 10 and the first output module 30 are electrically connected at a second node N2.

As still shown, the input control module 10 includes a first transistor M1, a second transistor M2 and a first capacitor C1. A gate electrode of the first transistor M1 is connected to the first clock terminal CK. A source electrode of the first transistor M1 is connected to the first level signal terminal VG1. A drain electrode of the first transistor M1 is connected to the second node N2. A gate electrode of the second transistor M2 is connected to the first node N1, a source electrode of the second transistor M2 is connected to the signal input terminal IN, a drain electrode of the second transistor M2 is connected to the second node N2. The first capacitor C1 is connected to the second node N2 and the second level signal terminal VG2. The input control module 10 controls activation or deactivation of the first transistor M1 based on the first clock signal. The first level signal from the first level signal terminal VG1 is transmitted to the second node N2 when the first transistor M1 is turned on. The second transistor M2 is turned on or turned off in accordance with the level of the first node N1. The first pulse signal received by the signal input terminal IN is transmitted to second node N2 when the second transistor M2 is turned on. The first capacitor C1 is used to maintain the level of the second node N2.

The first output module 30 is connected to the signal output terminal OUT and the second level signal terminal VG2. The second output module 40 is connected to the signal output terminal OUT and the second clock terminal CKB. The stabilizing module 20 is connected to the signal input terminal IN, the first clock terminal CK.

On the basis of the above technical solution, the first output module 30, the second output module 40 and the stabilizing module 20 each can be realized in a variety of circuits. The circuit shown in FIG. 3 is merely an example. The first output module 30, the second output module 40 and the stabilizing module 20 in accordance with the present disclosure are also not limited to this embodiment, and can be realized in other combination manners.

Specifically, referring to FIG. 3 again, the first output module 30 includes a third transistor M3; where a gate electrode of the third transistor M3 is connected to the second node N2, a source electrode of the third transistor M3 is connected to the second level signal terminal VG2, and a drain electrode of the third transistor M3 is connected to the signal output terminal OUT. Under the control of the level of the second node N2, the third transistor M3 can be turned on so that the second level signal terminal VG2 and the signal output terminal OUT are in electrical connection, and hence the second level signal, as the second pulse signal for outputting, is transmitted to the signal output terminal OUT.

The second output module 40 includes a fourth transistor M4 and a second capacitor C2. A gate electrode of the fourth transistor M4 is connected to the first node N1, a source electrode of the fourth transistor M4 is connected to the second clock terminal CKB, and a drain electrode of the fourth transistor M4 is connected to the signal output terminal OUT. The second capacitor C2 is connected between the first node N1 and the signal output terminal OUT. Under the control of the level of the first node N1, the fourth transistor M4 can be turned on so that the second clock terminal CKB and the signal output terminal OUT are in electrical connection, and hence the second clock signal, as the second pulse signal for outputting, is transmitted to the signal output terminal OUT. The second capacitor C2 is used to keep the level of the first node N1 or couple to the level of the first node N1.

The stabilizing module 20 includes a fifth transistor M5, where a gate electrode of the fifth transistor M5 is connected to the first clock terminal CK, a source electrode of the fifth transistor M5 is connected to the signal input terminal IN, and a drain electrode of the fifth transistor M5 is connected to the first node N1. The fifth transistor M5 is turned on or turned off under the control of the first clock signal. When the fifth transistor M5 is turned on, the first pulse signal received by the signal input terminal IN is transmitted to the first node N1, and it avoids the electricity leakage from the level of the first node N1 to the signal input terminal IN, thereby functioning the transmission and stability.

On the basis of the structure of the above shift register, the shift register includes a plurality of transistors, such as a first transistor M1, a second transistor M2, a third transistor M3, a fourth transistor M4 and a fifth transistor M5, which are all P-type channel thin film transistors. Based on this, a level of the first level signal is lower than a level of the second level signal, that is, the first level signal is a low level signal VGL for activation the P-type channel thin film transistor, the second level signal is a high level signal VGH for deactivation the P-type channel thin film transistor. Furthermore, a phase of the first clock signal is inverse to a phase of the second clock signal in a signal input phase, a signal output phase and a signal reset phase. The level states of the first clock signal and the second clock signal are a high level and a low level, respectively, where the level value of the high level is equal to the level value of the high level signal VGH and the level value of the low level is equal to the level value of the low level signal VGL. Furthermore, the first pulse signal and the second pulse signal have a first level state and a second level state at different phases. In the embodiment, the level value of the first level state is equal to the level value of the low level signal VGL, and the level value of the second level state is equal to the level value of the high level signal VGH.

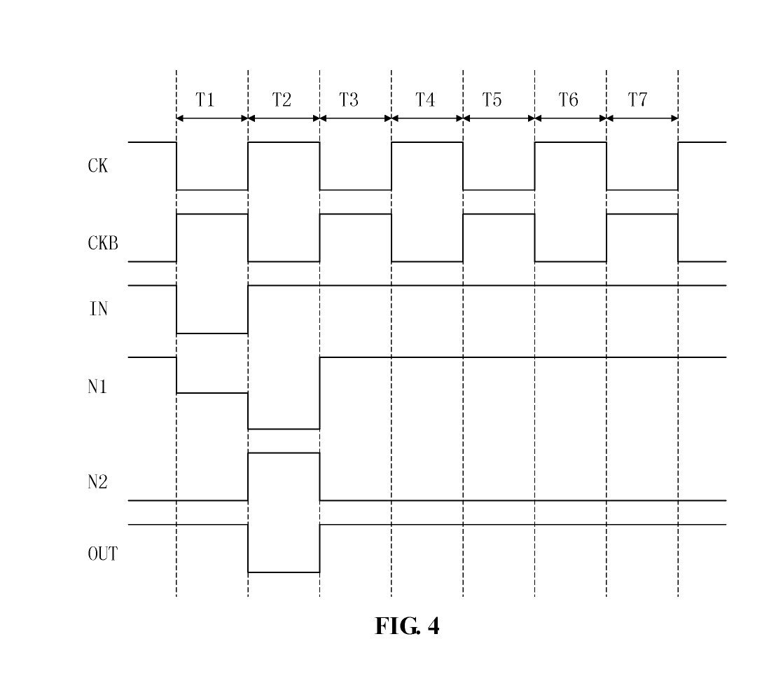

Referring to FIG. 4, FIG. 4 is a schematic view showing the driving timing of the shift register shown in FIG. 3. FIG. 4 will be described with reference to FIGS. 3.

In a signal input phase T1, the first transistor M1 is turned on, so that a first level signal from the first level signal terminal VG1 is transmitted to the second node N2. The stabilizing module 20 transmits a first pulse signal from the signal input terminal IN to the first node N1; the first output module 30 outputs a second level signal from the second level signal terminal VG2. The second output module 30 outputs a second clock signal from the second clock terminal CKB. he signal output terminal OUT receives the second level signal and the second clock signal, and outputs a second pulse signal.

Specifically, in the signal input phase T1, the first clock signal has a low level, the second clock signal CKB has a high level, and the first pulse signal inputted to the signal input terminal IN has a first level state, i.e. a low level signal VGL. The first clock signal controls the activation of the first transistor M1, so that the first level signal terminal VG1 and the second node N2 are in electrical connection, and hence the first level signal, i.e. a low level signal VGL, is transmitted to the second node N2. Under the function of the first capacitor C1, the second node N2 maintains a low level in the signal input phase T1.

The fifth transistor M5 of the stabilizing module 20 is turned on under control of the first clock signal so that the signal input terminal IN and the first node N1 are in electrical connection, and hence the first pulse signal from the signal input terminal IN is transmitted to the first node N1. Since the first pulse signal maintains a first level state (i.e. equal to the low level signal VGL) in the signal input phase T1, the first node N1 maintains a low level in the signal input phase T1.

Since the second node N2 has a low level, the third transistor M3 of the first output module 30 is turned on, so that the second level signal terminal VG2 and the signal output terminal OUT are in electrical connection, and hence the second level signal is transmitted to the signal output terminal OUT. That is, the high level signal VGH is transmitted to the signal output terminal OUT.

Since the first node N1 maintains a low level, the fourth transistor M4 is turned on, so that the second clock terminal CKB and the signal output terminal OUT are in electrical connection. As a result, the second clock signal is transmitted to the signal output terminal OUT. Since the second clock signal has a high level at this time, the level value thereof is equal to the level value of the high level signal VGH.

In short, the signal output terminal OUT receives the second level signal and the second clock signal in the signal input phase T1. Since level values of the second level signal and the second clock signal are equal to the level value of the high level signal VGH, the level of the second pulse signal outputted by the signal output terminal OUT during the signal input phase T1 is in a second level state. That is, it is equal to the level of the high level signal VGH.

In a signal output phase, the first transistor M1 is turned off; and the second transistor M2 is turned on, so that the first pulse signal is transmitted to the second node N2. The second output module 40 outputs the second clock signal from the second clock terminal CK. The signal output terminal OUT receives the second clock signal and outputs the second pulse signal.

Specifically, in the signal output phase T2, the first clock signal has a high level, the second clock signal has a low level, and the first pulse signal inputted to the signal input terminal IN has a second level state. That is, the first pulse signal inputted to the signal input terminal IN is a high level signal VGH. The first clock signal controls the deactivation of the first transistor M1. Further, under the control of the first clock signal, the fifth transistor M5 is turned off. When the fifth transistor M5 is turned off, the first node N1 maintains a low level of the preceding phase. The level of the first node N1 controls the activation of the fourth transistor M4, so that the second clock terminal CKB and the signal output terminal OUT are in electrical connection, and hence the second clock signal is transmitted to the signal output terminal OUT. Since the second clock signal has a low level in the signal output phase, the second pulse signal outputted from the signal output terminal maintains the first level state at this time. That is, the level value thereof is equal to the level value of the low level signal VGL. In the signal output phase, due to the coupling effect of the second capacitor, the level of the first node N1 is pulled down to a level which is lower than the level of the low level signal VGL, thereby ensuring that the fourth transistor M4 is turned on continuously and the signal is outputted from the signal output terminal OUT continuously.

Furthermore, in the signal output phase T2, since the level of the first node N1 is pulled down, the second transistor M2 connected to the first node N1 is turned on, so that the signal input terminal and the second node N2 are in electrical connection. In this phase, since the first pulse signal inputted to the signal input terminal IN maintains at the second level state—that is, the level value of the first pulse signal is equal to the level value of the high level signal VGH—the level of the second node N2 is pulled up, and the level value thereof is equal to the level value of the high level signal VGH. Under the control of the level of the second node N2, the third transistor M3 is turned off, so that the the second level signal terminal VG2 and the signal output terminal OUT is in electrical disconnection.

In short, in the signal output phase T2, the signal output terminal OUT only receives the second clock signal and outputs the second pulse signal maintained in the first level state.

In a signal reset phase T3, the first transistor M1 is turned on, so that the first level signal is transmitted from the first level signal terminal VG1 to the second node N2; the stabilizing module transmits the first pulse signal to the first node N1; the first output module 30 outputs the second level signal from the second level signal terminal VG2; and the signal output terminal receives the second level signal and outputs the second pulse signal.

Specifically, in the signal reset phase T3, the first clock signal has a low level, the second clock signal has a high level, and the first pulse signal inputted to the signal input terminal IN is at the second level state. That is the first pulse signal inputted to the signal input terminal INa high level signal VGH. The first clock signal controls the activation of the first transistor M1, so that the first level signal terminal VG1 and the second node N2 are in electrical connection, and hence the first level signal (i.e. the low level signal VGL) is transmitted to the second node N2. Under the function of the first capacitor C1, the second node N2 maintains at a low level in the signal reset phase T3.

Further, under the control of the first clock signal, the fifth transistor M5 is turned on, so that the first pulse signal is transmitted to the first node N1. Since the first pulse signal maintains at the second level state at this time, that is, the level value of the first pulse signal is equal to the level value of the high level signal VGH, the first node N1 maintains at a high level in the signal reset phase T3.

In the signal reset phase, the second node N2 maintains at a low level, the third transistor M3 is turned on, so that the second level signal terminal VG2 and the signal output terminal OUT are in electrical connection, and hence the second level signal is transmitted to the signal output terminal. The level of the first node N1 controls deactivation of the fourth transistor M4, so that the second clock signal terminal CKB and the signal output terminal OUT are in electrical disconnection. That is, in the signal reset phase, the signal output terminal OUT only receives the second level signal. Since the second level signal is a high level signal VGH, the signal output terminal OUT outputs the high level signal VGH in the signal reset phase, that is, the outputted second pulse signal maintains at the second level state.

At the time period after the signal reset phase T3, the first clock signal and the second clock signal vary alternately, and the first pulse signal inputted to the signal input terminal IN maintains at the second level state, that is, the first pulse signal is a high level signal VGH. At the time period thereafter, the level of the second node N2 is pulled down to a low level through activation of the first transistor M1, and the level of the first node N1 is pulled up a high level through activation of the fifth transistor M5. The second pulse signal outputted from the signal output terminal OUT maintains at the second level state, that is, the second pulse signal is a high level signal VGH.

According to the shift register and the driving method for the shift register provided by the present disclosure, the input control module and the stabilizing module control the activation of the first output module so as to transmit the second level signal from the second level signal terminal to the signal output terminal, or control the activation of the second output module so as to transmit the second clock signal from the second clock terminal to the signal output terminal, thereby enabling a secondary shift register to be in operation normally. The shift register provided by the present disclosure has an excellent stability, a better transmission, an excellent stable operation and a good performance, thereby solving problems of poor stability and unstable operation of the shift registers in the prior art.

It is noted that the P-type channel thin film transistor described herein is merely illustratively. In other embodiments, the plurality of transistors included in the shift register may be N-type channel thin film transistors. For example, the transistors as shown in FIG. 3 can be replaced with the N-type channel thin film transistors. In this case, the level of the first level signal is higher than the level of the second level signal. That is, the first level signal is the high level signal VGH, which turns on the N-type channel thin film transistor. The second level signal is the low level signal VGL which turns off the N-type channel thin film transistor. Furthermore, a phase of the first clock signal is inverse to a phase of the second clock signal in a signal input phase, a signal output phase and a signal reset phase, the two level states corresponding to the two clock signals are a high level and a low level, respectively, where the level value of the high level is equal to the level value of the high level signal VGH and the level value of the low level is equal to the level value of the low level signal VGL. The first pulse signal and the second pulse signal have a first level state and a second level state in different phases, where the level value of the first level state is equal to the level value of the high level signal VGH, and the level value of the second level state is equal to the level value of the low level signal VGL. That is, the level of the first level state is higher than the level of the second level state. A phase of the first clock signal is inverse to a phase of the second clock signal in a signal input phase, a signal output phase and a signal reset phase. The transistor is the N-type channel thin film transistor, and the driving sequence and principle thereof is the same as that of the P-type channel thin film transistor, which is not discussed again herein.

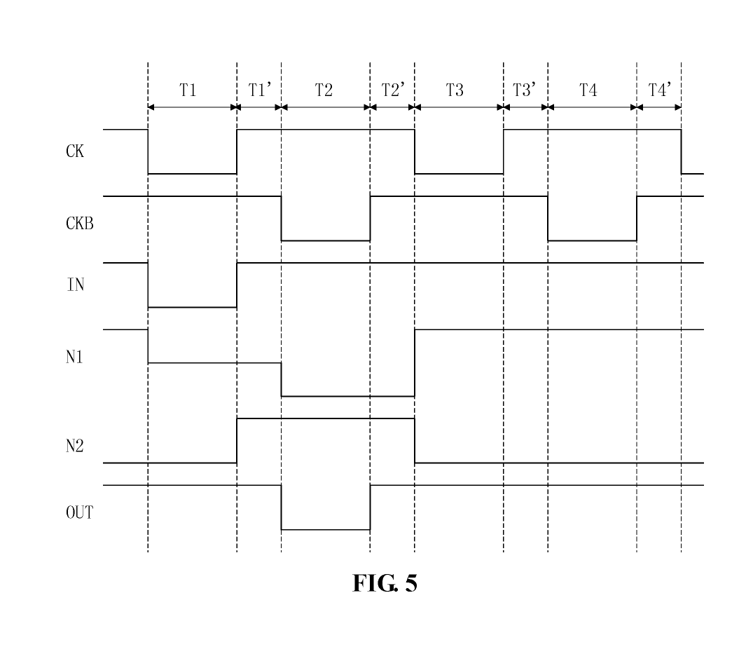

Referring to FIG. 5, FIG. 5 is a schematic view showing another driving time sequence of the shift register in FIG. 3. As compared with FIG. 4, FIG. 5 further includes a first transition phase T1′ and a second transition phase T2′. The first transition phase T1′ is between the signal input phase T1 and the signal output phase T2, and a phase of the first clock signal is same to a phase of the second clock signal in the first transition phase T1′.

The second transition phase T2′ is between the signal output phase T2 and the signal reset phase T3, and a phase of the first clock signal is same to a phase of the second clock signal in the second transition phase T2′.

According to the schematic view showing driving time sequence provided in the present embodiment, the signal input state and the signal output state corresponding to the shift register in the signal input phase T1, signal output phase T2 and the signal reset phase T3 are same as that shown in FIG. 4, which is not discussed again herein.

Reference is made in combination of FIGS. 3 with 5. In the first transition phase T1′, the first clock signal is changed to a high level, the second clock signal still remains a high level. Since the first clock signal is a high level in this phase, the first transistor M1 and the fifth transistor M5 are turned off, the first node N1 maintains at the level of the preceding phase, i.e., a low level, and the fourth transistor M4 is turned on, so that the second clock terminal CKB and the signal output terminal OUT are in electrical connection. Furthermore, since the first Node N1 has the low level, the second transistor M2 is turned on. At this time, since the first pulse signal inputted to the signal input terminal IN is changed to the second level state, i.e., the high level signal VGH, the high level signal is transmitted to the second node N2 via the second transistor M2, so that the second node N2 maintains the high level. Also at this time, the third transistor M3 is turned off, and hence the second level signal terminal VG2 and the signal output terminal OUT is in electrical disconnection. In the first transition phase T1′, the signal output terminal receives the second clock signal. Since at this time the second clock signal has a high level, the second pulse signal outputted from the signal output terminal is the second level state. That is, the level value of the second pulse signal is equal to the level value of the high level signal VGH, which is the same as the output level of the signal output terminal OUT in the signal input phase T1.

In the second transition phase T2′, the first clock signal maintains a high level of the signal output phase T2, and the second clock signal is changed from a low level to a high level. The inputting states and the outputting states of the input control module 10, the stabilizing module 20 and the first output module 30 in this phase are the same as those of the signal output phase T2, i.e., no change occurred. The second clock signal inputted to the fourth transistor M4 of the second output module 40 is changed. Since the first node has the low level in the signal output phase T2, the first node N1 still maintains the low level in the second transition phase T2′, the fourth transistor M4 maintains the activation state, and the second clock signal is changed from a low level to a high level, so that the second pulse signal outputted from the signal output terminal OUT is changed from the first level state to the second level state accordingly, that is, from the low level signal VGL to the high level signal. The outputting manner thereof in the second transition phase T2′ is the same to the outputting manner thereof in the signal reset phase T3.

According to the driving method for the shift register provided in this embodiment, the input control module and the stabilizing module control activation of the first output module so as to output the second level signal from the second level signal terminal to the signal output terminal, or control activation of the second output module so as to output the second clock signal from the second clock terminal to the signal output terminal, thereby making the secondary shift register to be in operation normally. The shift register in accordance with the present disclosure has an excellent stability, a better transmission and a good performance, thereby solving problems of poor stability and unstable operation of the shift registers in the prior art. Furthermore, since the transition phases are provided, the time period required for the changes of the level of the second node and the level of the signal outputted by the signal output terminal can be ensured, thereby making the output more stable.

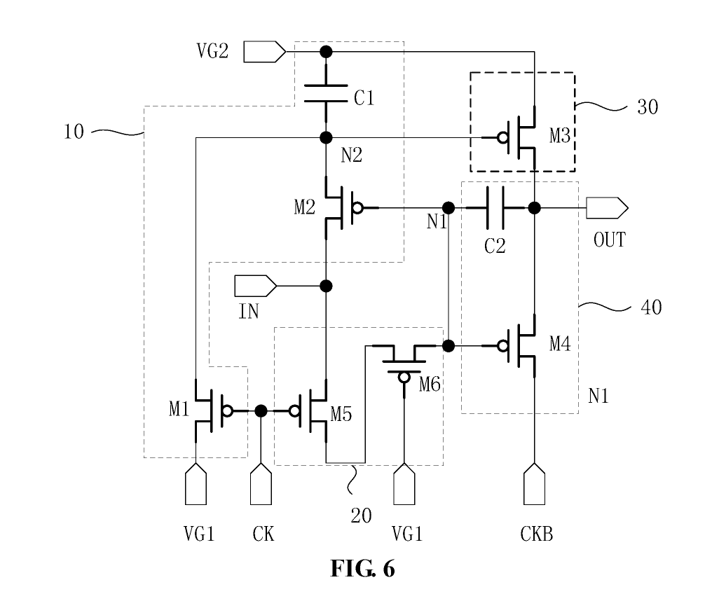

Referring to FIG. 6, FIG. 6 is a schematic view showing the structure of another shift register provided in an embodiment of the present disclosure. The connection relationship, the inputting and the outputting of the input control module 10, the first output module 30 and the second output module 40 of the shift register provided in FIG. 6 are the same as those of the shift register provided in FIG. 3, so that the specific structure of the shift register provided in FIG. 6 can be referred to the above relative description, which is not discussed again herein.

In the shift register provided in this embodiment, the stabilizing module 20 includes a fifth transistor M5 and a sixth transistor M6. A gate electrode of the fifth transistor M5 is connected to the first clock terminal CK, a source of the fifth transistor M5 is connected to the signal input terminal IN, and a drain of the fifth transistor M5 is connected to a source electrode of the sixth transistor M6; a gate electrode of the sixth transistor M6 is connected to the first level signal terminal VG1, and a drain electrode of the sixth transistor M6 is connected to the first node N1.

Under a normal operation state, since the gate electrode of the sixth transistor M6 is connected to the level signal terminal VG1, the first level signal from the first level signal terminal VG1 controls the sixth transistor M6 to still turn on , that is, under the normal operation state, the sixth transistor M6 can be approximately regarded as a length of wire, and the equivalent circuit diagram thereof is the same to the circuit diagram of the shift register provided in FIG. 3.

In the signal input phase, the first clock signal controls activation of the fifth transistor M5, the sixth transistor M6 is still turned on so that the first pulse signal inputted to the signal input terminal is transmitted to the first node. In the signal output phase, the first clock signal controls deactivation of the fifth transistor M5, so that the signal input terminal IN and the first node N1 is in electrical disconnection. In the signal reset phase, the first clock signal controls activation of the fifth transistor M5, the sixth transistor M6 is still turned on and the first pulse signal inputted to the signal input terminal is transmitted to the first node.

The driving time sequence corresponding to the shift register provided in the present embodiment is the same to that of the shift register provided in FIG. 3, and can be refer to the driving time sequences of FIGS. 4 and 5, which is not discussed again herein.

In the present embodiment, the sixth transistor M6 is provided, so that when the level of the first N1 is abnormal due to the abnormity of the circuit, it prevents the abnormal level of the first node N1 from being transmitted to the drain electrode of the fifth transistor M5, thereby increasing the stability of the circuit. According to the shift register provided in this embodiment, the input control module and the stabilizing module control activation of the first output module so as to output the second level signal from the second level signal terminal to signal output terminal, or control activation of the second output module so as to output the second clock signal from the second clock terminal to the signal output terminal, thereby making the secondary shift register to be in operation normally. The shift register provided by the present disclosure has an excellent stability, a better transmission and a good performance, thereby solving problems of poor stability and unstable operation of the shift register in the prior art.

The above content is a further detailed description made to the present disclosure by combining the specific preferable implementations and cannot be regarded that the specific implementations of the present disclosure only limited thereto. As for those skilled in the art, a plurality of simple modifications and variations can be made without departing from the spirit and idea of the invention, which should fall in the scope of the present disclosure.

1. A shift register, comprising:
an input control module, a first output module, a second output module, a stabilizing module, a signal input terminal, a signal output terminal, a first clock terminal, a second clock terminal, a first level signal terminal and a second level signal terminal; and, wherein
the signal input terminal is configured to receive a first pulse signal, the signal output terminal is configured to output a second pulse signal, the first clock terminal is configured to receive a first clock signal, the second clock terminal is configured to receive a second clock signal, the first level signal terminal is configured to receive a first level signal and the second level signal terminal is configured to receive a second level signal;
the input control module, the stabilizing module and the second output module are electrically connected at a first node;
the input control module and the first output module are electrically connected at a second node;
the input control module comprises a first transistor, a second transistor and a first capacitor, wherein a gate electrode of the first transistor is connected to the first clock terminal, a source electrode of the first transistor is connected to the first level signal terminal, a drain electrode of the first transistor is connected to the second node; a gate electrode of the second transistor is connected to the first node, a source electrode of the second transistor is connected to the signal input terminal, a drain electrode of the second transistor is connected to the second node; the first capacitor is connected between the second node and the second level signal terminal;
the second output module is connected to the signal output terminal and the second clock terminal;
the first output module is connected to signal output terminal and the second level signal terminal; and
the stabilizing module is connected to the signal input terminal and the first clock terminal, and the stabilizing module is configured to receive the first clock signal from the first clock terminal, and to control electrical connection and disconnection between the signal input terminal and the first node according to the first clock signal.

2. The shift register of claim 1, wherein
the first output module comprises a third transistor, wherein
a gate electrode of the third transistor is connected to the second node, a source electrode of the third transistor is connected to the second level signal terminal, and a drain electrode of the third transistor is connected to the signal output terminal.

3. The shift register of claim 1, wherein
the second output module comprises a fourth transistor and a second capacitor; wherein
a gate electrode of the fourth transistor is connected to the first node, a source electrode of the fourth transistor is connected to the second clock terminal, and a drain electrode of the fourth transistor is connected to the signal output terminal; and
the second capacitor is connected to the first node and the signal output terminal.

4. The shift register of claim 1, wherein
the stabilizing module comprises a fifth transistor and a sixth transistor, wherein
a gate electrode of the fifth transistor is connected to the first clock terminal, a source electrode of the fifth transistor is connected to the signal input terminal, and a drain electrode of the fifth transistor is connected to a source electrode of the sixth transistor; and
a gate electrode of the sixth transistor is connected to the first level signal terminal, and a drain electrode of the sixth transistor is connected to the first node.

5. The shift register of claim 1, wherein
the stabilizing module comprises a fifth transistor, wherein
a gate electrode of the fifth transistor is connected to the first clock terminal, a source electrode of the fifth transistor is connected to the signal input terminal, and a drain electrode of the fifth transistor is connected to the first node.

6. The shift register of claim 1, further comprising a plurality of transistors, wherein
the plurality of transistors are P-type channel thin film transistors.

7. The shift register of claim 6, wherein
a level of the first level signal is lower than a level of the second level signal; and a phase of the first clock signal is inverse to a phase of the second clock signal in a signal input phase, a signal output phase and a signal reset phase.

8. The shift register of claim 1, further comprising a plurality of transistors, wherein
the plurality of transistors are N-type channel thin film transistors.

9. The shift register of claim 8, wherein
a level of the first level signal is higher than a level of the second level signal; and a phase of the first clock signal is inverse to a phase of the second clock signal in a signal input phase, a signal output phase and a signal reset phase.

10. A driving method for a shift register, wherein the shift register comprises:
an input control module, a first output module, a second output module, a stabilizing module, a signal input terminal, a signal output terminal, a first clock terminal, a second clock terminal, a first level signal terminal and a second level signal terminal; wherein
the input control module, the stabilizing module and the second output module are electrically connected at a first node;
the input control module and the first output module are electrically connected at a second node;
the input control module comprises a first transistor, a second transistor and a first capacitor, wherein a gate electrode of the first transistor is connected to the first clock terminal, a source electrode of the first transistor is connected to the first level signal terminal, and a drain electrode of the first transistor is connected to the second node; a gate electrode of the second transistor is connected to the first node, a source electrode of the second transistor is connected to the signal input terminal, and a drain electrode of the second transistor is connected to the second node; the first capacitor is connected between the second node and the second level signal terminal;
the second output module is connected to the signal output terminal and the second clock terminal;
the first output module is connected to the signal output terminal and the second level signal terminal; and
the stabilizing module is connected to the signal input terminal and the first clock terminal, and the stabilizing module is configured to receive the first clock signal from the first clock terminal, and controlling electrical connection and disconnection between the signal input terminal and the first node according to the first clock signal;
the method comprises:
in a signal input phase,
activation the first transistor, so that a first level signal from the first level signal terminal is transmitted to the second node;
transmitting, at the stabilizing module, a first pulse signal from the signal input terminal to the first node;
outputting, at the first output module, a second level signal from the second level signal terminal;
outputting, at the second output module, a second clock signal from the second clock terminal; and
receiving, at the signal output terminal, the second level signal and the second clock signal and outputting a second pulse signal;
in a signal output phase,
deactivation the first transistor, and turning of the second transistor so that the first pulse signal is transmitted to the second node;
outputting, at the second output module, the second clock signal from the second clock terminal; and
receiving, at the signal output terminal, the second clock signal and outputting the second pulse signal; and
in a signal reset phase,
activation the first transistor being turned on, so that the first level signal is transmitted from the first level signal terminal to the second node;
transmitting, at the stabilizing module, the first pulse signal to the first node;
outputting, at the first output module, the second level signal from the second level signal terminal; and
receiving, at the signal output terminal, the second level signal and outputting the second pulse signal; and, wherein
the first pulse signal is at a first level state in the signal input phase, and is at a second level state in the signal output phase and the signal reset phase; the second pulse signal is at a first level state in the signal output phase, and is at a second level state in the signal input phase and the signal reset phase.

11. The driving method of claim 10, wherein
the first output module comprises a third transistor; a gate electrode of the third transistor is connected to the second node, a source electrode of the third transistor is connected to the second level signal terminal, and a drain electrode of the third transistor is connected to the signal output terminal;
the method further comprises:
in the signal input phase, activation the third transistor, so that the second level signal is transmitted to the signal output terminal;
in the signal output phase, deactivation the third transistor;
in the signal reset phase, activation the third transistor, so that the second level signal is transmitted to the signal output terminal.

12. The driving method of claim 10, wherein
the second output module comprises a fourth transistor and a second capacitor; a gate electrode of the fourth transistor is connected to the first node, a source electrode of the fourth transistor is connected to the second clock terminal, and a drain electrode of the fourth transistor is connected to the signal output terminal; and the second capacitor is connected between the first node and the signal output terminal;
the method further comprises:
in the signal input phase, activation the fourth transistor, so that the second clock signal is transmitted to the signal output terminal;
in the signal output phase, activation the fourth transistor, so that the second clock signal is transmitted to the signal output terminal;
in the signal reset phase, deactivation the fourth transistor by controlling a level of the first node.

13. The driving method of claim 10, wherein
the stabilizing module comprises a fifth transistor and a sixth transistor, wherein
a gate electrode of the fifth transistor is connected to the first clock terminal, a source electrode of the fifth transistor is connected to the signal input terminal, and a drain electrode of the fifth transistor is connected to a source electrode of the sixth transistor;
a gate electrode of the sixth transistor is connected to the first level signal terminal, and a drain electrode of the sixth transistor is connected to the first node;
the method further comprises:
in the signal input phase, activation both the fifth transistor and the sixth transistor , so that the first pulse signal is transmitted to the first node;
in the signal output phase, deactivation the fifth transistor;
in the signal reset phase, activation both the fifth transistor and the sixth transistor, so that the first pulse signal is transmitted to the first node.

14. The driving method of claim 10, wherein
the stabilizing module comprises a fifth transistor, wherein
a gate electrode of the fifth transistor is connected to the first clock terminal, a source electrode of the fifth transistor is connected to the signal input terminal, and a drain electrode of the fifth transistor is connected to the first node;
the method further comprises:
in the signal input phase, activation the fifth transistor, so that the first pulse signal is transmitted to the first node;
in the signal output phase, deactivation the fifth transistor;
in the signal reset phase, activation the fifth transistor, so that the first pulse signal is transmitted to the first node.

15. The driving method of claim 10, further comprising:
a first transition phase, wherein the first transition phase is between the signal input phase and the signal output phase, and a phase of the first clock signal is same to a phase of the second clock signal in the first transition phase;
a second transition phase, wherein the second transition phase is between the signal output phase and the signal reset phase, and a phase of the first clock signal is same to a phase of the second clock signal in the second transition phase.

16. The driving method of claim 10, wherein
the shift resister further comprises a plurality of transistors, and the plurality of transistors are P-type channel thin film transistors, wherein
a level of the first level signal is lower than a level of the second level signal; a phase of the first clock signal is inverse to a phase of the second clock signal at the signal input phase, the signal output phase and the signal reset phase; and a level of the first level state is lower than a level of the second level state.

17. The driving method of claim 10, wherein
the shift register further comprises a plurality of transistors, and the plurality of transistors are N-type channel thin film transistors, and
wherein a level of the first level signal is higher than a level of the second level signal; a phase of the first clock signal is inverse to a phase of the second clock signal at the signal input phase, the signal output phase and the signal reset phase; and a level of the first level state is higher than a level of the second level state.
